(19) United States
(12) Patent Application Publication
(10) Pub. No.: US 2025/0210469 A1
(43) Pub. Date: Jun. 26, 2025

(54) MIXED DEPTH CAVITY FOR EMBEDDED BRIDGE STRUCTURES

(71) Applicant: Intel Corporation, Santa Clara, CA (US)

(72) Inventors: Brandon C. MARIN, Gilbert, AZ (US); Numair AHMED, Chandler, AZ (US); Srinivas Venkata Ramanuja PIETAMBARAM, Chandler, AZ (US); Jeremy D. ECTON, Gilbert, AZ (US); Gang DUAN, Chandler, AZ (US); Benjamin DUONG, Phoenix, AZ (US); Suddhasattwa NAD, Chandler, AZ (US); Bohan SHAN, Chandler, AZ (US)

(21) Appl. No.: 18/391,327

(22) Filed: Dec. 20, 2023

(51) Int. Cl. H01L 23/482; H01L 23/00; H01L 23/498; H01L 25/065

(52) U.S. Cl. CPC H01L 23/4821; H01L 23/49816; H01L 23/49822; H01L 24/08; H01L 24/16; H01L 25/0652; H01L 2224/08146; H01L 2224/08155; H01L 2224/16146; H01L 2224/16157; H01L 2924/1421; H01L 2924/1432; H01L 2924/1434

(57) ABSTRACT

Embodiments disclosed herein comprise an apparatus. In an embodiment, the apparatus comprises a substrate with a first cavity into the substrate. In an embodiment, the first cavity has a first depth. In an embodiment, a second cavity is provided into the substrate, where the second cavity has a second depth that is different than the first depth. In an embodiment, a first die is in the first cavity, where the first die has a first thickness. In an embodiment, a second die is in the second cavity, where the second die has a second thickness that is different than the first thickness.

### BACKGROUND

Computing architectures continue to scale to smaller form factors while pushing towards higher bandwidths and computing capacity. One solution for enabling such design goals is to use chiplet architectures. Instead of a single large chip, a plurality of smaller chiplets are stitched together by a bridge. When the bridge is embedded in the underlying package substrate, the bridge may be referred to as an embedded bridge solution. Existing bridge solutions typically do not allow for power to pass through a thickness of the bridge. Instead, traces are routed over the bridge in order to provide power within the footprint of the bridge. This complicates routing and increases the length of the power delivery path, which can impact performance.

In some instances, a bridge with vias is used in order to provide routing through a thickness of the bridge instead of routing around the bridge. However, this can lead to the use of multiple different types of bridge structures within a package substrate. For example, a first bridge may include vias, and a second bridge may not include vias. Such differences may lead to differences in the thicknesses of the bridges. As such, integration of the bridges into the package substrate is complicated. For example, cavities with different depths may be needed in order to accommodate the different types of bridges.

### BRIEF DESCRIPTION OF THE DRAWINGS

FIG. 1A is a cross-sectional illustration of a package substrate with an embedded bridge that includes power routing that wraps around the bridge, in accordance with an embodiment.

FIG. 1B is a cross-sectional illustration of a package substrate with an embedded bridge that includes power routing through a thickness of the bridge, in accordance with an embodiment.

FIG. 2A is a cross-sectional illustration of a package substrate with a first bridge with a first thickness and a second bridge with a second thickness, in accordance with an embodiment.

FIG. 2B is a cross-sectional illustration of a package substrate with a first bridge that is in a cavity through the buildup layers, and a second bridge that is in a cavity that does not pass entirely through the buildup layers, in accordance with an embodiment.

FIG. 3A is a cross-sectional illustration of a package substrate with a cavity for a bridge, where the cavity has vertical sidewalls, in accordance with an embodiment.

FIG. 3B is a cross-sectional illustration of a package substrate with a cavity for a bridge, where the cavity has sloped sidewalls, in accordance with an embodiment.

FIG. 3C is a cross-sectional illustration of a package substrate with a cavity for a bridge, where the cavity has saw-toothed profiled sidewalls, in accordance with an embodiment.

FIG. 3D is a cross-sectional illustration of a package substrate with a cavity for a bridge, where the cavity has sidewalls with offset vertical portions, in accordance with an embodiment.

FIGS. 4A-4K are cross-sectional illustrations depicting a process for forming a package substrate with cavities that have non-uniform depths for accommodating different types of bridge structures, in accordance with an embodiment.

FIG. 5 is a cross-sectional illustration of a package substrate with a first bridge in a first cavity and a second bridge in a second cavity that is formed at the edge of the package substrate, in accordance with an embodiment.

FIG. 6 is a cross-sectional illustration of an electronic system with a package substrate that includes different bridge architectures and cavities with different depths, in accordance with an embodiment.

FIG. 7 is a schematic of a computing device built in accordance with an embodiment.

### EMBODIMENTS OF THE PRESENT DISCLOSURE

Described herein are electronic systems, and more particularly, architectures with package substrates that include cavities with different depths to accommodate different types of bridge dies, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, electronic packaging architectures are moving towards the inclusion of various embedded bridge architectures. The bridge is a building block that allows for the communicative coupling of various chiplets. Depending on the needs of the system, two or more different types of bridges may be used within a single package substrate. For example, a standard bridge structure may be used. A standard bridge structure may include high density routing in order to link chiplets together. A second type of bridge structure may include vias that pass through a thickness of the bridge in addition to the high density routing. The vias may be referred to as through silicon vias (TSVs) when the bridge is a silicon substrate or die. The different types of bridge structures may require different types of integration processes. Accordingly, the ability to integrate various bridge architectures is necessary in order to manufacture advanced electronic packaging architectures.

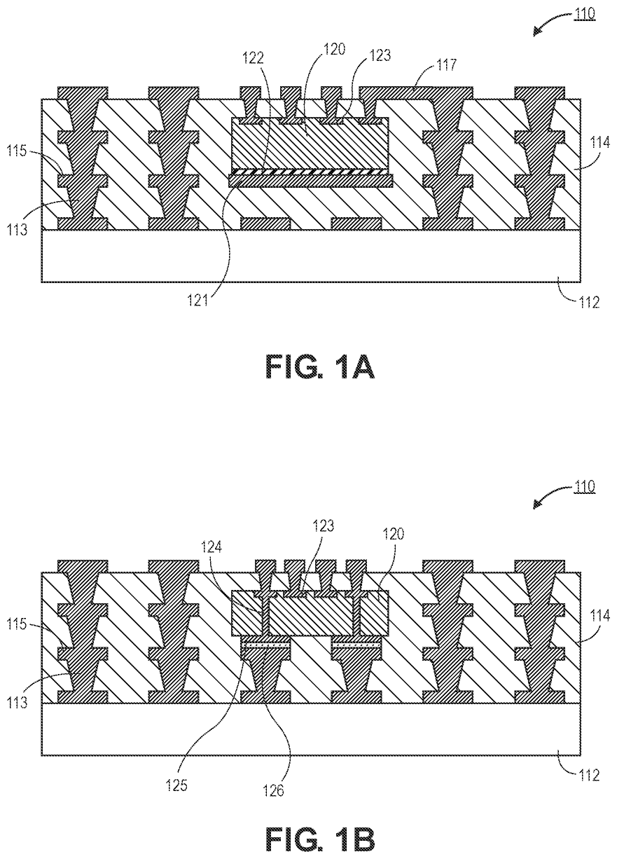

An example of a typical embedded bridge structure is shown in FIG. 1A. In FIG. 1A, a cross-sectional illustration of a package substrate 110 is shown, in accordance with an embodiment. In an embodiment, the package substrate 110 comprises a core 112. The core 112 may be any suitable core material. For example, the core 112 may comprise an organic core with glass fiber reinforcement or the core 112 may comprise a substantially solid glass layer. While shown as a monolithic structure, the core 112 typically includes electrically conductive vias that pass through a thickness of the core 112. In an embodiment, buildup layers 114 may be provided over the core 112. Buildup layers 114 may also be provided over the bottom of the core 112. The bottom portion of the package substrate 110 is omitted from FIG. 1A for clarity since the bridge 120 is located in the top portion of the package substrate 110. The buildup layers 114 may comprise an organic dielectric material. For example, multiple dielectric layers may be laminated over each other in order to form the larger structure of the buildup layers 114. In an embodiment, the buildup layers 114 may comprise electrically conductive routing, such as vias 113, pads 115, traces 117, and the like. The electrically conductive routing may comprise copper, copper alloys, or other metallic materials.

In an embodiment, the bridge 120 is embedded within the buildup layers 114. The bridge 120 may also be referred to as a “die” or a “bridge die” in some embodiments. The bridge 120 may be a dimensionally stable material. For example, the bridge 120 may comprise silicon, other semiconductor materials, a ceramic, s glass, or the like. In an embodiment, electrically conductive routing (e.g., traces, pads, etc.) may be provided on the bridge 120. For example, pads 123 are shown in FIG. 1A. In some instances, the routing may be provided in back-end-of-line (BEOL) layers (not shown) over the dimensionally stable base material (e.g., silicon). The BEOL layers may include dielectric materials, such as silicon oxide, silicon nitride, organic dielectrics, and the like. The dimensional stability of the bridge 120 allows for fine line and space (L/S) dimensions in order to provide electrical coupling between overlying dies (not shown in FIG. 1A). In an embodiment, the bridge 120 may be provided over an etchstop layer 121. The etchstop layer 121 may comprise copper or the like. The bridge 120 may be secured to the etchstop layer 121 by an adhesive 122 or the like.

In the illustrated embodiment, there are no vias through a thickness of the bridge 120. Accordingly, power is not able to be routed through the bridge 120. Instead, power is provided in a path that passes adjacent to a sidewall of the bridge 120. Once above the level of the top surface of the bridge 120, a trace 117 can route power into the footprint of the bridge 120. This increases the length of the power delivery path and decreases performance. Additionally, the lateral routing makes routing within the package substrate 110 more complicated.

Accordingly, embodiments disclosed herein may utilize a bridge 120 that includes vias 124. An example of such an embodiment is shown in FIG. 1B. As shown, the vias 124 pass through at least a portion of the thickness of the bridge 120. Pads 125 at the bottom of the bridge 120 are coupled to pads 123 at the top of the bridge 120 through the vias 124. In an embodiment, the bottom pads 125 are coupled to pads 115 in the buildup layers 114 through a solder 126 or the like. In order to make the necessary electrical connections, the thickness variation of the buildup layers 114 needs to be low.

When a glass core 112 is used, thickness variation is typically improved. The improvement is maximized as the bridge 120 is moved closer to the surface of the glass core 112. That is, reducing the thickness of the buildup layers 114 between the bridge 120 and the core 112 is beneficial. However, as the bridge 120 is moved closer to the core 112, potential for damaging the core 112 is increased. The core 112 is brittle and is prone to cracking or other damage. Accordingly, some amount of buffer layer is currently necessary between the core 112 and the bottom of the bridge 120.

As can be appreciated, the bridge 120 in FIG. 1A may be a different thickness than the bridge 120 in FIG. 1B. As such, the respective cavities into the buildup layers 114 need to be formed to different depths in order to accommodate the different heights of the bridges 120. This may require different fabrication process in the assembly of the buildup layers. In some instances, the cavities may be formed with laser drilling processes that include etchstop layers formed at different depths. In other instances, the photoimageable dielectrics (PIDs) can be used in order to use photolithography in order to form the cavities.

The different manufacturing and assembly processes may result in cavities that have unique or different profiles. For example, the cavities may have vertical sidewalls or sloped sidewalls. In other embodiments, the cavities may have a saw-tooth shaped profile with each tooth being part of a different layer of the buildup layers. Additionally, cavities may be formed from a plurality of stacked cavities. These stacked cavities may be misaligned with each other and provide a distinctive sidewall profile.

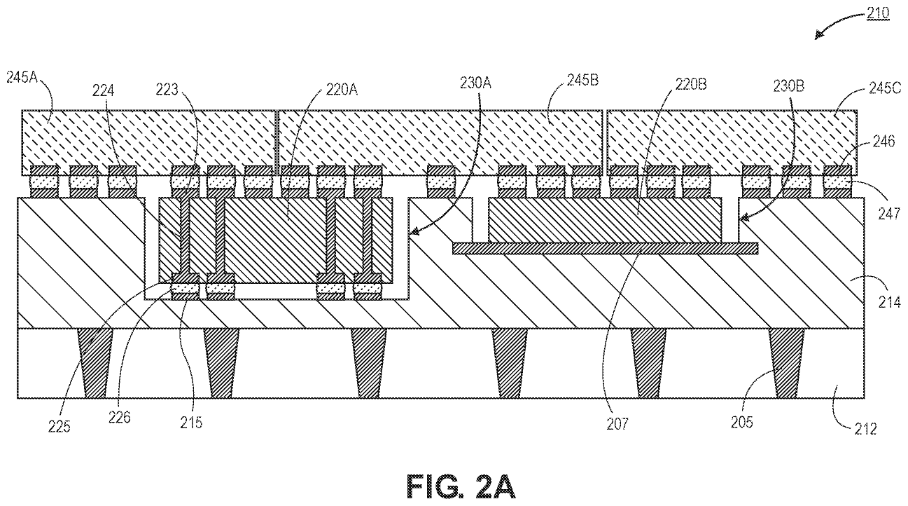

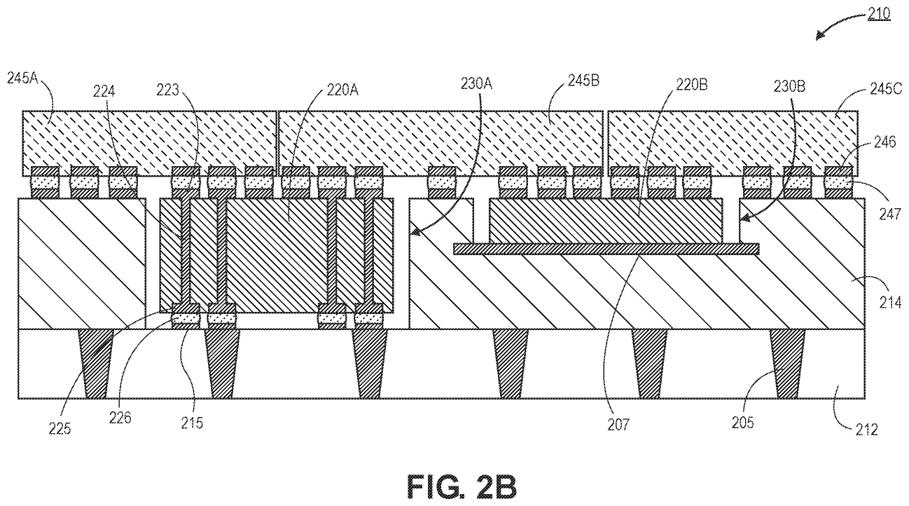

Referring now to FIG. 2A, a cross-sectional illustration of a package substrate 210 is shown, in accordance with an embodiment. In an embodiment, the package substrate 210 comprises a core 212 and buildup layers 214 over the core 212. In the illustrated embodiment, buildup layers 214 are only shown above the core 212. However, it is to be appreciated that buildup layers 214 (with associated electrical routing) may also be provided below the core 212.

Vias 205 may be provided through a thickness of the core 212. The vias 205 may be an electrically conductive material, such as copper or an alloy of copper. In an embodiment, the vias 205 may have any suitable cross-sectional shape. For example, in FIG. 2A, the vias 205 have sloped sidewalls so that a top of the via 205 is wider than a bottom of the via 205. In other embodiments, the vias 205 may have substantially vertical sidewalls. Other embodiments may include vias 205 with hourglass shaped cross-sections.

In an embodiment, the core 212 may be a glass layer or an organic dielectric material. In the case of an organic dielectric material, reinforcing fibers may be provided within the core 212. For example, glass fibers or the like may be embedded in the core 212. In the case of a glass layer, the core 212 may be substantially all glass. The core 212 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, core 212 may be distinguished from, for example, the “prepreg” or “RF4” core of a Printed Circuit Board (PCB) substrate which typically comprises glass fibers embedded in a resinous organic material, such as an epoxy.

The core 212 may have any suitable dimensions. In a particular embodiment, the core 212 may have a thickness that is approximately 50 μm or greater. For example, the thickness of the core 212 may be between approximately 50 μm and approximately 1.4 mm. Though, smaller or larger thicknesses may also be used. The core 212 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the core 212 (from an overhead plan view) may be between approximately 10 mm×10 mm and approximately 250 mm×250 mm. In an embodiment, the core 212 may have a first side that is perpendicular or orthogonal to a second side. In a more general embodiment, the core 212 may comprise a rectangular prism volume with sections (e.g., vias) removed and filled with other materials (e.g., metal, etc.).

The core 212 may comprise a single monolithic layer of glass. In other embodiments, the core 212 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the core 212 may each have a thickness less than approximately 50 μm. For example, discrete layers of glass in the core 212 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The core 212 may be any suitable glass formulation that has the necessary mechanical robustness and compatibility with semiconductor packaging manufacturing and assembly processes. For example, the core 212 may comprise aluminosilicate glass, borosilicate glass, alumino-borosilicate glass, silica, fused silica, or the like. In some embodiments, the core 212 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the core 212 may comprise silicon and oxygen, as well as any one or more of aluminum, boron, magnesium, calcium, barium, tin, sodium, potassium, strontium, phosphorus, zirconium, lithium, titanium, or zinc. In an embodiment, the core 212 may comprise at least 23 percent silicon (by weight) and at least 26 percent oxygen (by weight). In some embodiments, the core 212 may further comprise at least 5 percent aluminum (by weight).

In an embodiment, the buildup layers 214 may comprise organic dielectric material, such as buildup film. For example, two or more layers of buildup film may be laminated over each other in order to form the larger structure of the buildup layers 214. The buildup layers 214 may comprise electrical routing (not shown), such as vias, pads, traces, and the like. The electrical routing may be fabricated along with the formation of the buildup layers 214 using standard packaging processes.

In an embodiment, a plurality of bridge dies 220 may be inserted or embedded within the buildup layers 214. As used herein, a bridge die 220 may also be referred to as a bridge, a die, or a substrate. The bridge dies 220 may include material suitable for providing high density or fine line/space (L/S) routing. This high density routing is used to communicative couple together overlying dies 245. For example, the bridge dies 220 may comprise silicon or another semiconductor material. Glass, ceramic, or the like may also be used in accordance with certain embodiments. In some instances, the bridge dies 220 may comprise a substrate layer with an overlying dielectric routing layer (not shown) that may comprise dielectric layers (e.g., silicon dioxide, silicon nitride, etc.). Such overlying dielectric routing layers may be referred to as BEOL layers in some instances.

In the illustrated embodiment, the package substrate 210 includes a pair of bridge dies 220A and 220B. The two bridge dies 220A and 220B may be different from each other. For example, the first bridge die 220A may include vias 224. The vias 224 may be TSVs that pass at least partially through a thickness of the bridge die 220A. The vias 224 may electrically couple pads 225 at a bottom of the bridge die 220A to pads 223 at a top of the bridge die 220A. This allows for the routing of power, signals, etc. through a thickness of the bridge die 220A instead of needing to route power around the bridge die 220A. As such, the bridge die 220A may be electrically coupled to pads 215 on the buildup layers 214 by interconnects 226 (e.g., solder, etc.). In other instances, the bridge die 220A may be hybrid bonded to the pads 215. The second bridge die 220B may include a standard bridge structure without vias. As such, there may not need to be an electrical connection at the bottom of the bridge die 220B. This allows for the bottom of the cavity 230B to be terminated at an etchstop layer 207. For example, the etchstop layer 207 may be a metallic layer, such as a copper layer.

In an embodiment, the differences in the bridge dies 220A and 220B may result in the need for different cavity 230 architectures. For example, the cavity 230A is deeper than the cavity 230B. That is, a distance between the bottom surface of cavity 230A and the core 212 may be smaller than a distance between a bottom surface of cavity 230B and the core 212. The difference in the cavity 230 depths may be enabled through any number of package assembly processes, as will be described in greater detail below. In an embodiment, the difference in the depths may be at least approximately 5 μm different from each other, at least 10 μm different from each other, at least 20 μm different from each other, or at least 50 μm different from each other. Though, smaller differences may also be used in some instances.

In an embodiment, the bridges 220A and 220B may communicatively couple together overlying dies 245. For example, three dies 245A, 245B, and 245C are shown in FIG. 2A. The first die 245A and the second die 245B are communicatively coupled together by the first bridge die 220A, and the second die 245B and the third die 245C are communicatively coupled together by the second bridge die 220B. The dies 245 may have pads 246 that are coupled to the pads 223 through interconnects 247, such as any first level interconnect (FLI) architecture (e.g., solder, copper bumps, hybrid bonding, etc.). The dies 245 may be any type of die, such as a central processing unit (CPU), a graphics processing unit (GPU), an XPU, a communications die, a memory die, an application-specific integrated circuit (ASIC), a field-programmable gate array (FPGA), or the like.

In the embodiment shown in FIG. 2A, the bridge dies 220A and 220B are placed in the cavities 230A and 230B without any underfill or embedding material. Though, in some instances, an underfill or molding material may be provided around interconnects 226 and/or fill (or at least partially fill) the remainder of the cavities 230A and 230B.

Referring now to FIG. 2B, a cross-sectional illustration of a package substrate 210 is shown, in accordance with an additional embodiment. As shown, the package substrate 210 in FIG. 2B is substantially similar to the package substrate 210 in FIG. 2A, with the exception of the structure of the first cavity 230A. Instead of having a bottom surface that is provided within a thickness of the buildup layers 214, the first cavity 230A passes entirely through a thickness of the buildup layers 214. That is, the first cavity 230A has a bottom surface that exposes a top surface of the core 212. In some instances, the bottom pads 225 of the first bridge die 220A may be coupled to vias 205 by interconnects 226 and a pad 215 that are not embedded in the buildup layers 214.

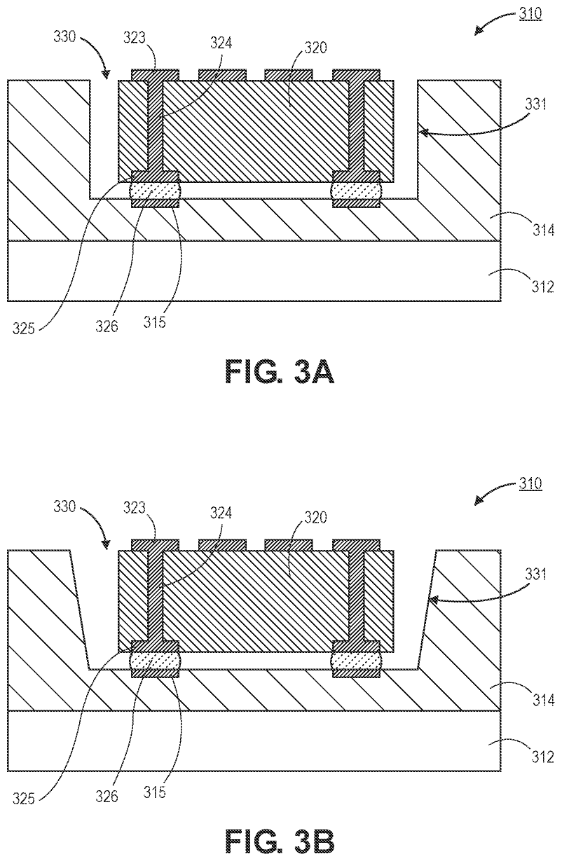

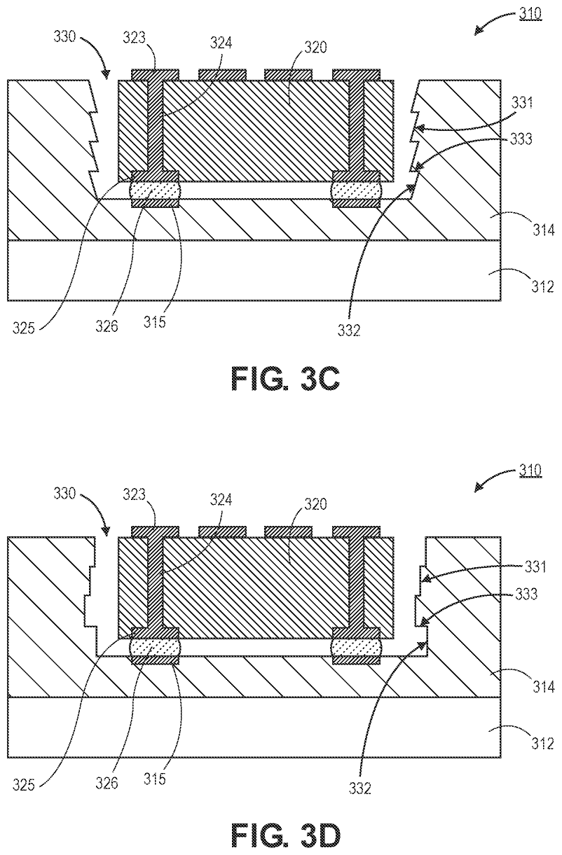

Referring now to FIGS. 3A-3D, several cross-sectional illustrations depicting examples of bridge dies 320 in cavities 330 are shown, in accordance with various embodiments. In the illustrated embodiments, a single cavity 330 and bridge die 320 are shown. However, it is to be appreciated that a given package substrate 310 may include two or more cavity 330 and bridge die 320 pairs. In such instances, each pair may have different structures. For example, the depth of the different cavities may be different from each other. However, the sidewall structure of the different cavities may be similar to each other. That is, the different cavities may be formed with the same manufacturing processes. In other embodiments, the different cavities may have different sidewall structures. In these instances, the different cavities may be formed with different manufacturing processes.

Referring now to FIG. 3A, a cross-sectional illustration of a portion of a package substrate 310 is shown, in accordance with an embodiment. The package substrate 310 may include a core 312 and buildup layers 314 over the core 312. While not shown, buildup layers 314 may also be provided below the core 312. The core 312 may also comprise vias (not shown). The core 312 and the buildup layers 314 may be similar to any of the core structures or buildup layer structures described in greater detail below.

In an embodiment, a cavity 330 may be formed into the top surface of the buildup layer 314. The cavity 330 may have sidewalls 331. In an embodiment, the sidewalls 331 may have substantially vertical profiles. As used herein, “substantially vertical” may refer to a surface that is within approximately 10 degrees of being orthogonal from the top surface of the buildup layers 314. Such sidewall 331 profiles may be formed through the use of an etching process, a drilling process, or any other suitable manufacturing process.

In an embodiment, a bridge die 320 may be inserted into the cavity 330. The bridge die 320 may include vias 324 that connect pads 325 to pads 323. Though, other embodiments may include bridge dies 320 without vias 324 or bottom pads 325. In the case shown in FIG. 3A, the pads 325 may be coupled to pads 315 by interconnects 326 (e.g., solder or the like). While not shown, an underfill or molding material may at least partially fill a remainder of the cavity 330.

Referring now to FIG. 3B, a cross-sectional illustration of a portion of a package substrate 310 is shown, in accordance with an additional embodiment. In an embodiment, the package substrate 310 may be substantially similar to the package substrate 310 in FIG. 3A, with the exception of the profile of the sidewalls 331. Instead of being substantially vertical, the sidewalls 331 may have a sloped profile. The sloping profile of the sidewalls 331 may provide a cavity 330 that has a top width that is wider than a bottom width. In an embodiment, the slop of the sidewalls 331 may be provided as a result of the patterning process used to form the cavity 330. For example, a laser ablation process may be used in order to form the cavity 330. That is, the buildup layers 314 may be fully formed, and a single laser ablation process may be used in order to form a continuous (e.g., linear) sloping sidewall 331.

Referring now to FIG. 3C, a cross-sectional illustration of a portion of a package substrate 310 is shown, in accordance with another embodiment. As shown, the package substrate 310 may be substantially similar to the package substrate 310 in FIG. 3A, with the exception of the profile of the sidewalls 331. Instead of having a linear profile, the sidewalls 331 may have a saw tooth shaped profile. For example, the sidewalls 331 may have a sloped vertical portion 332 and a substantially horizontal portion 333 between each vertical portion 331. As used herein, “substantially horizontal” may refer to a surface that is within 10 degrees of being parallel to the top surface of the buildup layers 314. Such a saw toothed profile may be formed by patterning each layer of the buildup layers 314 as it is laminated over an underlying layer. For example, each layer may be laser drilled or etched after it is laminated.

Referring now to FIG. 3D, a cross-sectional illustration of a portion of a package substrate 310 is shown, in accordance with an additional embodiment. The package substrate 310 in FIG. 3D may be substantially similar to the package substrate 310 in FIG. 3A, with the exception of the profile of the sidewalls 331. Instead of having a linear profile, the sidewalls 331 may have offset portions. That is, substantially vertical portions 332 may be separated from each other by substantially horizontal portions 333. Such an embodiment may be the result of patterning processes for each layer of the buildup layers 314 that are at least partially misaligned from each other. Accordingly, the profile of the cavity 330 may have sidewalls 331 with a jagged or otherwise non-uniform profile.

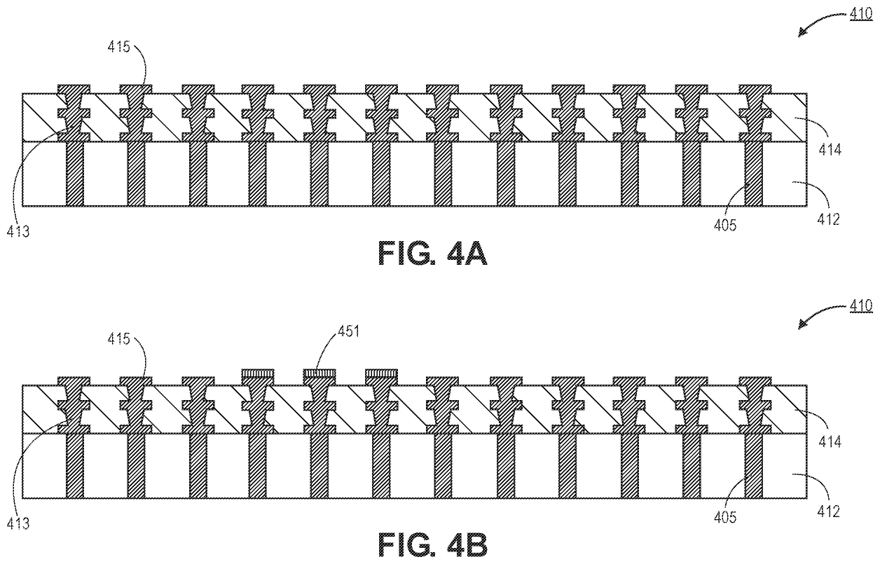

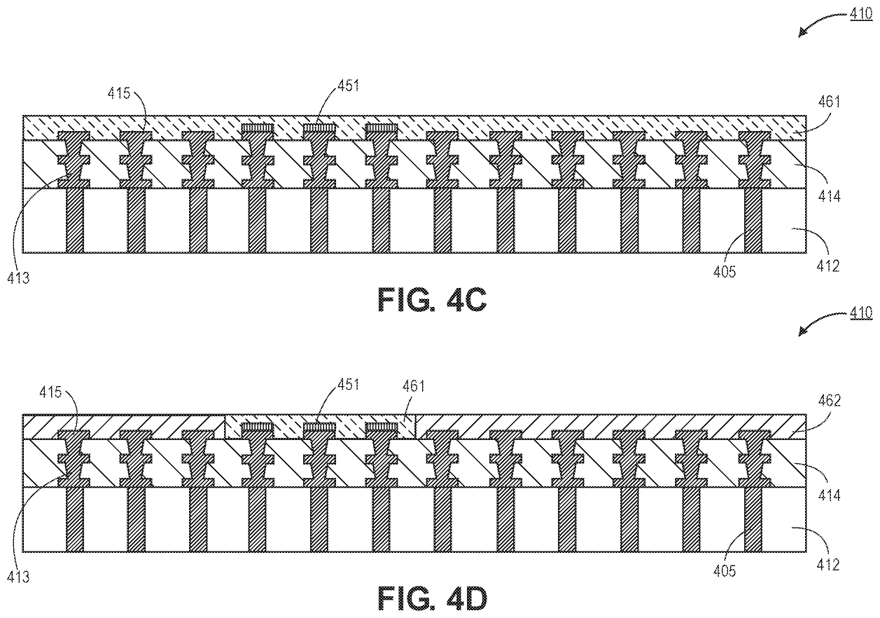

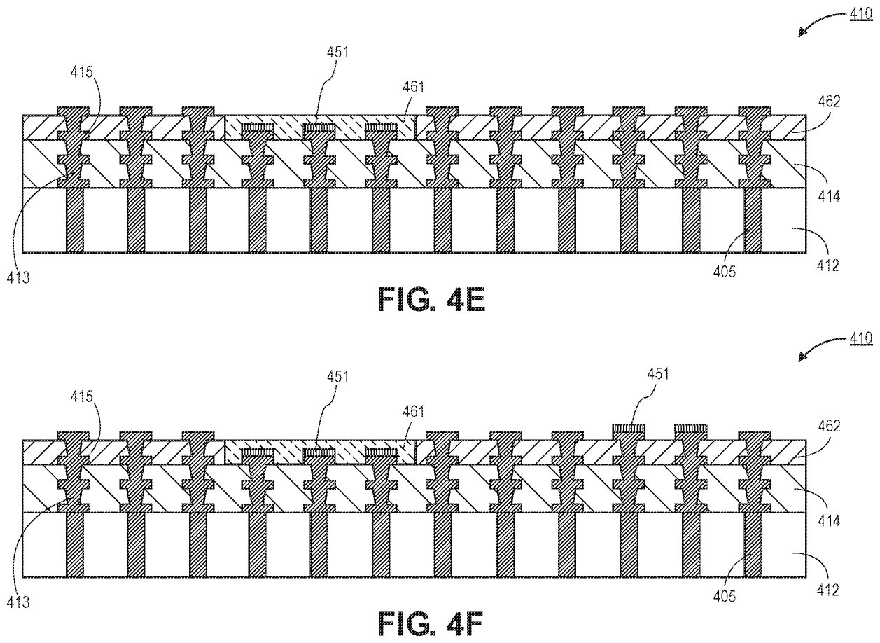

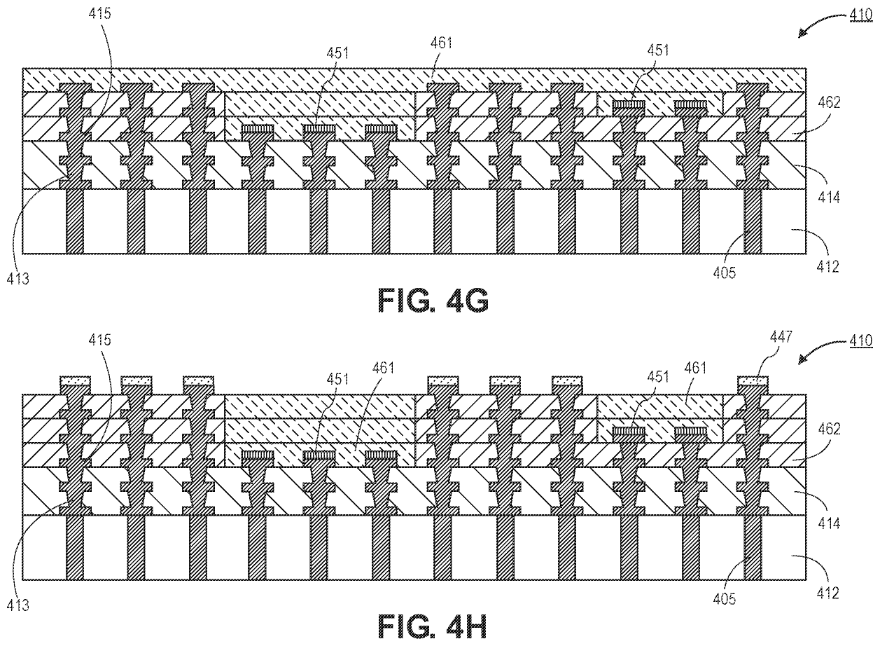

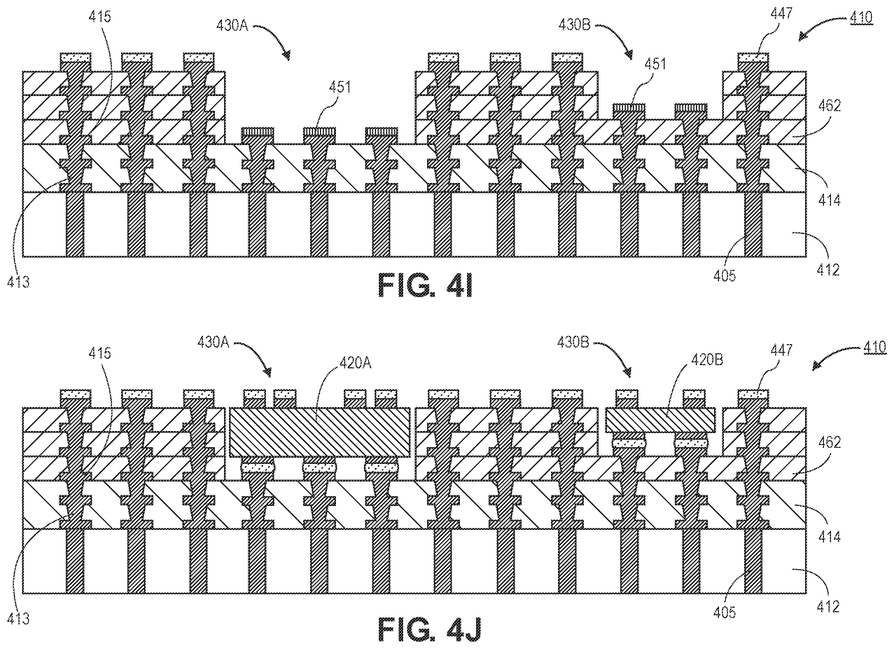

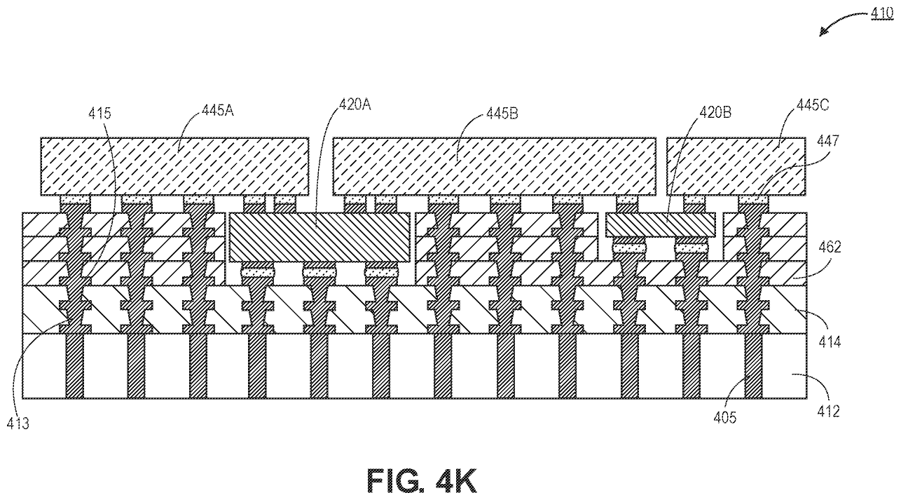

Referring now to FIGS. 4A-4K, a series of cross-sectional illustrations depicting a process for forming a package substrate 410 with non-uniform cavity 430 depths is shown, in accordance with an embodiment. While one process flow is shown, it is to be appreciated that other methods and processes may be used in order to form the cavities 430 as well.

Referring now to FIG. 4A, a cross-sectional illustration of a portion of a package substrate 410 at a stage of manufacture is shown, in accordance with an embodiment. In an embodiment, the package substrate 410 may comprise a core 412 with buildup layers 414 over the core 412. While not shown, buildup layers 414 may also be provided below the core 412. The core 412 may be similar to any of the core structures described in greater detail herein. The buildup layers 414 may also be similar to any of the buildup layers described in greater detail herein. In an embodiment, vias 405 may be provided through a thickness of the core 412. Electrical routing may be provided in the buildup layers 414. For example, pads 415 and vias 413 may be provided in the buildup layers 414 in some embodiments.

Referring now to FIG. 4B, a cross-sectional illustration of the package substrate 410 at a different stage of manufacture is shown, in accordance with an embodiment. The package substrate 410 may have a surface finish 451 plated on certain ones of the pads 415. Particularly, the pads 415 that will be provided in the deepest cavity may be covered by a surface finish 451. The surface finish 451 may comprise any suitable surface finish material, such as gold, silver, platinum, or the like. The surface finish 451 may be used for oxidation resistance, a diffusion barrier, or the like.

Referring now to FIG. 4C, a cross-sectional illustration of the package substrate 410 at a subsequent manufacturing stage is shown, in accordance with an embodiment. As shown, a layer 461 is applied over the top surface of the buildup layers 414. The layer 461 may be a photoimageable dielectric (PID), or the like. The layer 461 may be deposited with any suitable process, such as lamination, spin coating, or the like. The layer 461 may cover the exposed top pads 415 and any associated surface finish 451.

Referring now to FIG. 4D, a cross-sectional illustration of the package substrate 410 at a stage of manufacture is shown, in accordance with an additional embodiment. As shown, the layer 461 is patterned in order to form exposed regions 462. For example, a photolithography process or the like may be used in order to produce a latent image in the layer 461. The exposed regions 462 may be cross-linked or otherwise resistant to an etching process that will be used in a subsequent patterning operation. In an embodiment, the layer 461 persists around the pads 415 that are covered with the surface finish 451. This region will ultimately become part of the cavity.

Referring now to FIG. 4E, a cross-sectional illustration of the package substrate 410 at an advanced stage of manufacture is shown, in accordance with an embodiment. As shown, electrical routing is provided through the exposed regions 462 and over the exposed regions 462. For example, vias 413 may be provided through a thickness of the exposed regions 462, and pads 415 may be provided over the exposed regions 462. The electrical routing may be formed with traditional patterning and plating process used in package substrate manufacturing.

Referring now to FIG. 4F, a cross-sectional illustration of the package substrate 410 at a different stage of manufacture is shown, in accordance with an embodiment. As shown, surface finishes 451 may be provided over one or more of the pads 415 at the top of the exposed regions 462. These pads 415 may be the pads that are to be provided at the bottom of a second cavity in the package substrate 410. As can be appreciated, the pads 415 that are covered with surface finishes 451 at this operation are at a different level of the package substrate 410 than those covered by a surface finish 451 in FIG. 4B. As such, the depth of the subsequently formed cavities will be different.

Referring now to FIG. 4G, a cross-sectional illustration of the package substrate 410 at an additional stage of manufacture is shown, in accordance with an embodiment. As shown, additional layers 461 are applied over the first exposed region 462. The additional layers 461 may also be PIDs that are patterned to have exposed regions 462 and layers 461. In an embodiment, repeated exposures of each layer may result in unexposed sections of layers 461 being stacked over each other in order to form latent images of cavity regions. In the illustrated embodiment, the latent images of cavity regions are perfectly aligned. Though, in other instances, some misalignment may be present along the edges of the latent images.

Referring now to FIG. 4H, a cross-sectional illustration of the package substrate 410 after multiple layers 461 and exposed regions 462 are stacked above each other is shown, in accordance with an embodiment. Further, electrical routing (e.g., vias 413, pads 415, etc.) may be provided through the exposed regions 462. Solder 447 may be provided over the topmost pads 415. As shown, the latent image of layers 461 on the left is three layers deep, and the latent image of layers 461 on the right is two layers deep. As such, the subsequently formed cavities will have different depths.

Referring now to FIG. 4I, a cross-sectional illustration of the package substrate 410 after the cavities 430 are formed is shown, in accordance with an embodiment. As shown, a first cavity 430A is deeper than a second cavity 430B. The cavities 430A and 430B may be formed through the use of an etching process. The etching process may selectively remove the layers 461, while leaving behind the exposed regions 462. Though, other subtractive processes may be used in some instances.

Referring now to FIG. 4J, a cross-sectional illustration of the package substrate 410 at an additional stage of manufacture is shown, in accordance with an embodiment. In an embodiment, bridge die 420A may be inserted into the first cavity 430A, and bridge die 420B may be inserted into the second cavity 430B. In some embodiments, the bridge dies 420A and/or 420B may comprise vias (not shown) in order to route power and/or signals through thicknesses of the bridge dies 420A and/or 420B. The bridge dies 420A and 420B may be coupled to the buildup layers 414 through interconnects, such as solder or the like. In some cases, where the bridge die 420 does not have electrical routing through its thickness, the bottom of the bridge 420 may be coupled to a metal etchstop layer or the like.

Referring now to FIG. 4K, a cross-sectional illustration of the package substrate 410 after dies 445 are attached is shown, in accordance with an embodiment. As shown, three dies 445A, 445B, and 445C are attached to the package substrate 410 through interconnects 447. The bridge die 420A may communicatively couple the die 445A to the die 445B, and the bridge die 420B may communicatively couple the die 445B to the die 445C. The dies 445 may be any type of die, such as those described in greater detail herein.

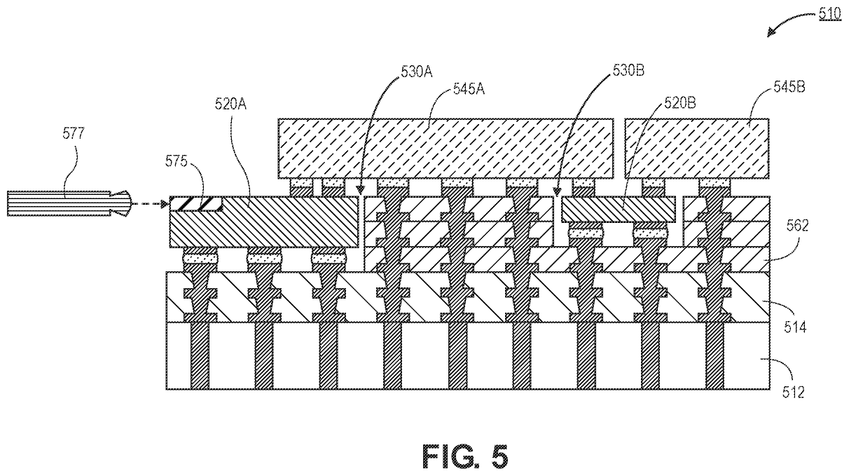

Referring now to FIG. 5, a cross-sectional illustration of a package substrate 510 is shown, in accordance with an embodiment. As shown, the package substrate 510 comprises a core 512 with buildup layers 514. The core 512 and buildup layers 514 may be similar to any core or buildup layer structures described in greater detail herein. In an embodiment, exposed regions 562 may be provided over the buildup layers 514. The exposed regions 562 may comprise PID material or the like, similar to embodiments described in greater detail herein.

In an embodiment, a first cavity 530A is provided through an entire thickness of the exposed regions 562. Further, the first cavity 530A may be at an edge of the package substrate 510. The first cavity 530A may have an open or exposed side. That is, at least one sidewall of the first cavity 530A may be omitted in some embodiments. In an embodiment, a second cavity 530B may be provided through one or more layers of the exposed regions 562. For example, a depth of the second cavity 530B may be shallower than a depth of the first cavity 530A.

In an embodiment, a first bridge die 520A is inserted into the first cavity 530A, and a second bridge die 520B is inserted into the second cavity 530B. The first bridge die 520A may be an optical component. For example, an optical-electrical transducer 575 (with one or more of a photodiode, a laser, electrical circuitry, lenses, or the like) may be integrated into the first bridge die 520A. The transducer 575 allows an optical signal from a cable 577 (e.g., a fiber optic cable or the like) to be converted into an electrical signal that can be propagated to a first die 545A. Similarly, the transducer 575 may allow electrical signals from the first die 545A to be converted into an optical signal and delivered to the cable 577. In an embodiment, the second bridge die 520B may communicatively couple the first die 545A to the second die 545B.

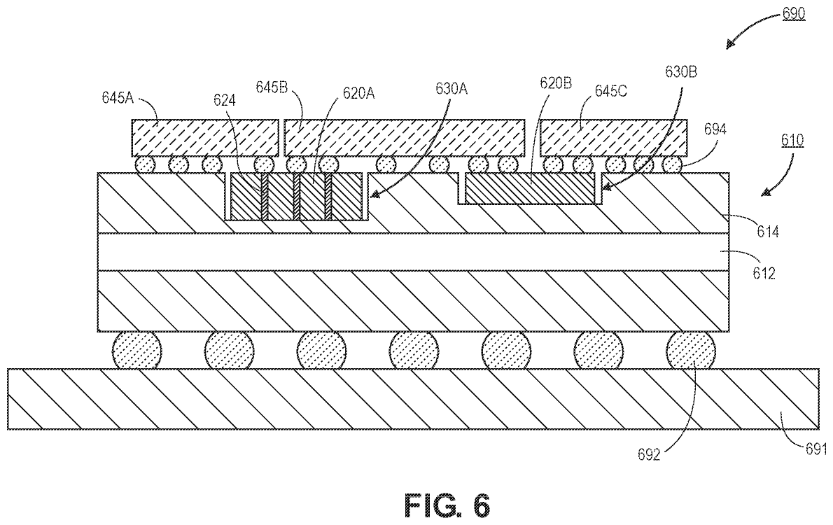

Referring now to FIG. 6, a cross-sectional illustration of an electronic system 690 is shown, in accordance with an embodiment. In an embodiment, the electronic system 690 comprises a board 691, such as a printed circuit board (PCB), a motherboard, or the like. The board 691 may be coupled to a package substrate 610 by interconnects 692. The interconnects 692 may be any suitable second level interconnect (SLI) architecture, such as solder balls, sockets, pins, or the like.

In an embodiment, the package substrate 610 may be similar to any of the package substrate architectures described in greater detail herein. For example, the package substrate 610 may include a core 612 with buildup layers 614. In an embodiment, a first cavity 630A and a second cavity 630B may be provided into the buildup layers 614. The first cavity 630A may have a different depth than the second cavity 630B. A first bridge die 620A may be in the first cavity 630A, and a second bridge die 620B may be in the second cavity 630B. One or both of the first bridge die 620A or the second bridge die 620B may have vias 624 through at least a portion of the first bridge die 620A or the second bridge die 620B.

In an embodiment, one or more dies 645 may be coupled to the package substrate 610 through interconnects 694. The interconnects 694 may be any suitable first level interconnect (FLI) architecture. For example, interconnects 694 may comprise solder, copper bumps, hybrid bonding architectures, or the like. The first bridge die 620A may communicatively couple the first die 645A to the second die 645B, and the second bridge die 620B may communicatively couple the second die 645B to the third die 645C. The dies 645 may be similar to any of the dies described in greater detail herein.

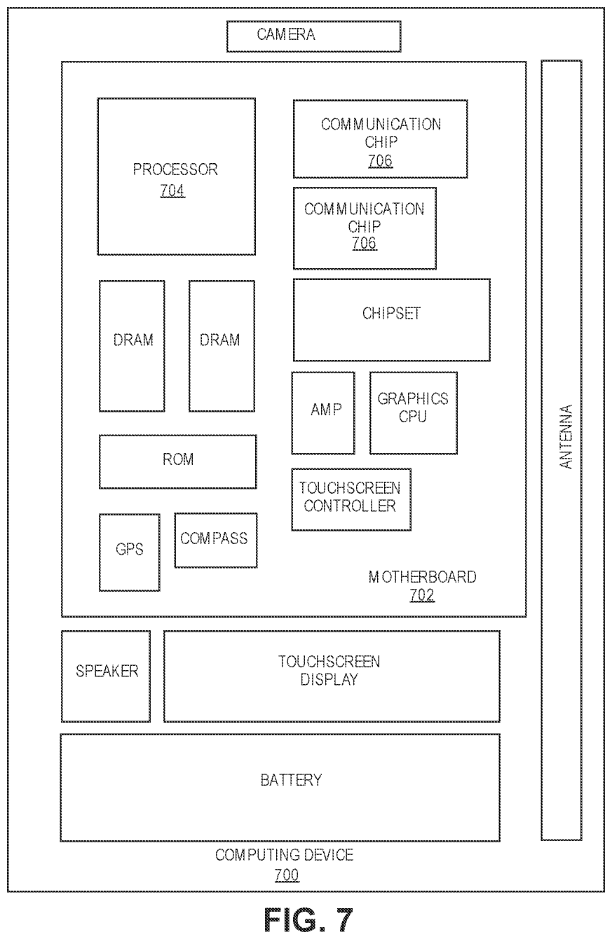

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic package that includes a first cavity with a first depth and a second cavity with a second depth that is different than the first depth, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic package that includes a first cavity with a first depth and a second cavity with a second depth that is different than the first depth, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; a first cavity into the substrate, wherein the first cavity has a first depth; a second cavity into the substrate, wherein the second cavity has a second depth that is different than the first depth; a first die in the first cavity, wherein the first die has a first thickness; and a second die in the second cavity, wherein the second die has a second thickness that is different than the first thickness.

Example 2: the apparatus of Example 1, wherein the first die comprises a via that passes at least partially through a thickness of the first die.

Example 3: the apparatus of Example 2, further comprising: a metallic layer embedded in the substrate below the second cavity, wherein the second die is coupled to the metallic layer.

Example 4: the apparatus of Examples 1-3, wherein sidewalls of the first cavity are substantially orthogonal to a top surface of the substrate.

Example 5: the apparatus of Examples 1-4, wherein sidewalls of the first cavity are non-orthogonal to a top surface of the substrate.

Example 6: the apparatus of Examples 1-5, wherein sidewalls of the first cavity have a stepped profile.

Example 7: the apparatus of Example 6, wherein vertical portions of the stepped profile have a slope.

Example 8: the apparatus of Examples 1-7, wherein the first depth is at least approximately 10 μm deeper than the second depth.

Example 9: the apparatus of Examples 1-8, wherein the first cavity pass entirely through a thickness of the substrate.

Example 10: the apparatus of Examples 1-9, further comprising: a second substrate under the substrate, wherein the second substrate comprises a solid glass layer with a rectangular prism form factor.

Example 11: an apparatus, comprising: a core, wherein the core comprises a solid glass layer; a layer over the core, wherein the layer comprises an organic dielectric; a first cavity into the layer; a second cavity into the layer; a first die in the first cavity; and a second die in the second cavity, wherein a first distance between the core and a bottom surface of the first cavity is smaller than a second distance between the core and a bottom surface of the second cavity.

Example 12: the apparatus of Example 11, wherein the first die comprises: a via through at least a portion of a thickness of the first die, wherein the via is electrically conductive.

Example 13: the apparatus of Example 12, further comprising: a second via through the core, wherein the via is electrically coupled to the second via by one or more electrically conductive structures between a bottom of the first cavity and the top of the core.

Example 14: the apparatus of Examples 11-13, wherein a bottom surface of the second cavity comprises a metal layer.

Example 15: the apparatus of Examples 11-14, wherein sidewalls of the first cavity and the second cavity have stepped profiles.

Example 16: the apparatus of Examples 11-15, wherein sidewalls of the first cavity and the second cavity have sloped profiles.

Example 17: an apparatus, comprising: a board; a package substrate coupled to the board, wherein the package substrate comprises: a core; a layer over the core; a first bridge in the layer with a first thickness; and a second bridge in the layer with a second thickness that is different than the first thickness; and a die coupled to the package substrate, wherein the die is electrically coupled to the first bridge and the second bridge.

Example 18: the apparatus of Example 17, wherein the first bridge comprises a vias least partially through a thickness of the first bridge.

Example 19: the apparatus of Example 17 or Example 18, wherein the core comprises a solid glass layer with a thickness that is at least 25 μm.

Example 20: the apparatus of Examples 17-19, wherein the apparatus is part of a personal computer, a server, a mobile device, a tablet, or an automobile.

What is claimed is:

1. An apparatus, comprising:
a substrate;
a first cavity into the substrate, wherein the first cavity has a first depth;
a second cavity into the substrate, wherein the second cavity has a second depth that is different than the first depth;
a first die in the first cavity, wherein the first die has a first thickness; and
a second die in the second cavity, wherein the second die has a second thickness that is different than the first thickness.

2. The apparatus of claim 1, wherein the first die comprises a via that passes at least partially through a thickness of the first die.

3. The apparatus of claim 2, further comprising:
a metallic layer embedded in the substrate below the second cavity, wherein the second die is coupled to the metallic layer.

4. The apparatus of claim 1, wherein sidewalls of the first cavity are substantially orthogonal to a top surface of the substrate.

5. The apparatus of claim 1, wherein sidewalls of the first cavity are non-orthogonal to a top surface of the substrate.

6. The apparatus of claim 1, wherein sidewalls of the first cavity have a stepped profile.

7. The apparatus of claim 6, wherein vertical portions of the stepped profile have a slope.

8. The apparatus of claim 1, wherein the first depth is at least approximately 10 μm deeper than the second depth.

9. The apparatus of claim 1, wherein the first cavity pass entirely through a thickness of the substrate.

10. The apparatus of claim 1, further comprising:
a second substrate under the substrate, wherein the second substrate comprises a solid glass layer with a rectangular prism form factor.

11. An apparatus, comprising:
a core, wherein the core comprises a solid glass layer;
a layer over the core, wherein the layer comprises an organic dielectric;
a first cavity into the layer;
a second cavity into the layer;
a first die in the first cavity; and
a second die in the second cavity, wherein a first distance between the core and a bottom surface of the first cavity is smaller than a second distance between the core and a bottom surface of the second cavity.

12. The apparatus of claim 11, wherein the first die comprises:
a via through at least a portion of a thickness of the first die, wherein the via is electrically conductive.

13. The apparatus of claim 12, further comprising:
a second via through the core, wherein the via is electrically coupled to the second via by one or more electrically conductive structures between a bottom of the first cavity and the top of the core.

14. The apparatus of claim 11, wherein a bottom surface of the second cavity comprises a metal layer.

15. The apparatus of claim 11, wherein sidewalls of the first cavity and the second cavity have stepped profiles.

16. The apparatus of claim 11, wherein sidewalls of the first cavity and the second cavity have sloped profiles.

17. An apparatus, comprising:
a board;
a package substrate coupled to the board, wherein the package substrate comprises:
a core;
a layer over the core;
a first bridge in the layer with a first thickness; and
a second bridge in the layer with a second thickness that is different than the first thickness; and
a die coupled to the package substrate, wherein the die is electrically coupled to the first bridge and the second bridge.

18. The apparatus of claim 17, wherein the first bridge comprises a vias least partially through a thickness of the first bridge.

19. The apparatus of claim 17, wherein the core comprises a solid glass layer with a thickness that is at least 25 μm.

20. The apparatus of claim 17, wherein the apparatus is part of a personal computer, a server, a mobile device, a tablet, or an automobile.
